(19) United States
(12) Patent Application Publication
(10) Pub. No.: US 2013/0299683 A1
(43) Pub. Date: Nov. 14, 2013

(54) OPTICAL CONNECTING MEMBER AND OPTICAL MODULE

(71) Applicant: Sumitmo Electric Industries, Ltd., Osaka-shi (JP)

(72) Inventors: Mitsuaki Tamura, Yokohama-shi (JP); Michiko HARUMOTO, Yokohama-shi (JP); Takayuki SHIMAZU, Yokohama-shi (JP); Masaki OYAGI, Yokohama-shi (JP)

(73) Assignee: Sumitomo Electric Industries, Ltd., Osaka-shi (JP)

(21) Appl. No.: 13/890,765

(22) Filed: May 9, 2013

(30) Foreign Application Priority Data
May 9, 2012 (JP) 2012-107286

(51) Int. Cl. H01L 31/0232

(52) U.S. Cl. CPC H01L 31/02327
USPC 250/216

(57) ABSTRACT

An optical connecting member includes a board chip, an optical element mounted on the board chip, and a lens member including a lens part optically connected to the optical element. An accommodating space for accommodating the optical element is formed between the lens member and the board chip. The accommodating space communicates with the outside only through a very small communicating part.

### CROSS-REFERENCE TO RELATED APPLICATION(S)

The present application claims the benefit of priority of Japanese Patent Application No. 2012-107286, filed on May 9, 2012. The disclosures of the application are incorporated herein by reference.

### BACKGROUND

1. Technical Field

The present disclosure relates to an optical connecting member and an optical module which can perform conversion between an electric signal and an optical signal.

2. Related Art

In the patent reference 1, an optical transmission device (optical connecting member) includes an optical element, an accommodating member (board) adapted for accommodating the optical element, and an optical waveguide (lens member) coupled to the optical element and adapted for closing an opening part of the accommodating member. This optical waveguide is attached to the accommodating member by means of an adhesive agent so as to close the opening part.

### PRIOR ART REFERENCE

### Patent Reference

### [Patent Reference 1]

Japanese Patent Application Laid Open No. 2010-152075

Meanwhile, it is conceivable that a lens member is formed by a resin having high heat resistance in the optical connecting member so that the lens member can be collectively mounted on the board together with the optical element by making use of solder reflow.

However, even if a resin having high heat resistance is used, since a melting temperature of solder is higher than a glass transition point of the resin, there is the possibility that such a lens member may be deformed by heat at the time of solder reflow.

Moreover, the optical connecting member has a large difference between a temperature at the time of the operation and a temperature at the time of non-operation, and such a large temperature change is repeatedly exerted on the lens member. For this reason, in the case where a lens member is attached to a board, the lens member expands or contracts by such temperature change so that a large stress is repeatedly exerted on the adhesive agent. For this reason, there is the possibility that the lens member may slip off from the board.

In addition, the optical connecting member is configured so that the optical element is mounted on the board with a light receiving surface being upwardly directed and the lens member is provided so as to cover the optical element from the upper direction thereof. Accordingly, since heat produced at the optical element is shaded by the lens member, there is the possibility that radiation of the optical element may not be sufficiently made.

### SUMMARY

Exemplary embodiments of the invention provide an optical connecting member and an optical module in which thermal deformation of the lens member is suppressed, adhesive force is not lowered, and the heat radiation performance of the optical element is improved.

An optical connecting member according to an exemplary embodiment comprises:

a board chip;

an optical element mounted on the board chip; and

a lens member including a lens part optically connected to the optical element,

wherein an accommodating space for accommodating the optical element is formed between the lens member and the board chip, and

wherein the accommodating space communicates with the outside only through a very small communicating part.

In optical connecting member, the communicating part may be a through-hole provided at the board chip.

Metallic plating may be implemented to an inner circumferential surface of the through-hole.

In the optical connecting member, the lens member may be fixed by an adhesive agent to the board chip except for a part of the lens member, and the communicating part may be a gap between the part where the adhesive agent of the lens member is not coated and the board chip.

In optical connecting member, the communicating part may be a through-hole provided at the lens member.

In the optical connecting member may further comprise:

a drive circuit adapted to drive the optical element, mounted on the board chip and accommodated within the accommodating space; and

a heat radiating member having one end thermally connected to the drive circuit and the other end extended toward outside of the accommodating space,

wherein an insertion hole is provided at the lens member,

wherein the heat radiating member is extended toward outside of the accommodating space through the inserting hole, and

wherein the communicating part is a gap between the heat radiating member and the inserting hole.

The optical connecting member may further comprise:

a water-proof ventilation filter provided at the communicating part.

An optical module according to an exemplary embodiment comprises:

the optical connecting member;

a mounting board on which the board chip is mounted; and

a housing adapted to accommodate the board chip and the mounting board,

wherein the heat radiating member is thermally connected to the housing.

In accordance with the optical connecting member and the optical module according to the exemplary embodiments of the present invention, since the accommodating space within which the optical element is accommodated communicates with the outside through the communicating part provided on the board, heat is difficult to stay within the lens member, and thermal deformation of the lens member is suppressed. In addition, since the lens member is difficult to rise in temperature at the time of the operation of the optical module, stress loaded onto the adhesive agent is reduced, and adhesion between the lens member and the board chip is thus maintained successfully.

### BRIEF DESCRIPTION OF THE DRAWINGS

FIG. 1 is a cross sectional view of an optical module on which an optical connecting member according to a first embodiment of the present invention is mounted.

FIG. 2 is a cross sectional view of the optical connecting member according to the first embodiment of the present invention.

FIG. 3 is a cross sectional view of an optical connecting member according to a second embodiment of the present invention.

FIG. 4 is a cross sectional view of an optical connecting member according to a third embodiment of the present invention.

FIG. 5 is a cross sectional view of an optical connecting member according to a fourth embodiment of the present invention.

FIG. 6 is a cross sectional view of an optical module on which the optical connecting member of FIG. 5 is mounted.

### DETAILED DESCRIPTION

### First Embodiment

A first embodiment of an optical connecting member 10 according to the present invention will now be described with reference to the attached drawings. This optical connecting member 10 serves to perform mutual conversion between an electric signal and an optical signal, and is mounted on, e.g., an optical module 1 serving to replace electric signals between electronic equipments into optical signals corresponding thereto to perform transmission of signals at a high speed.

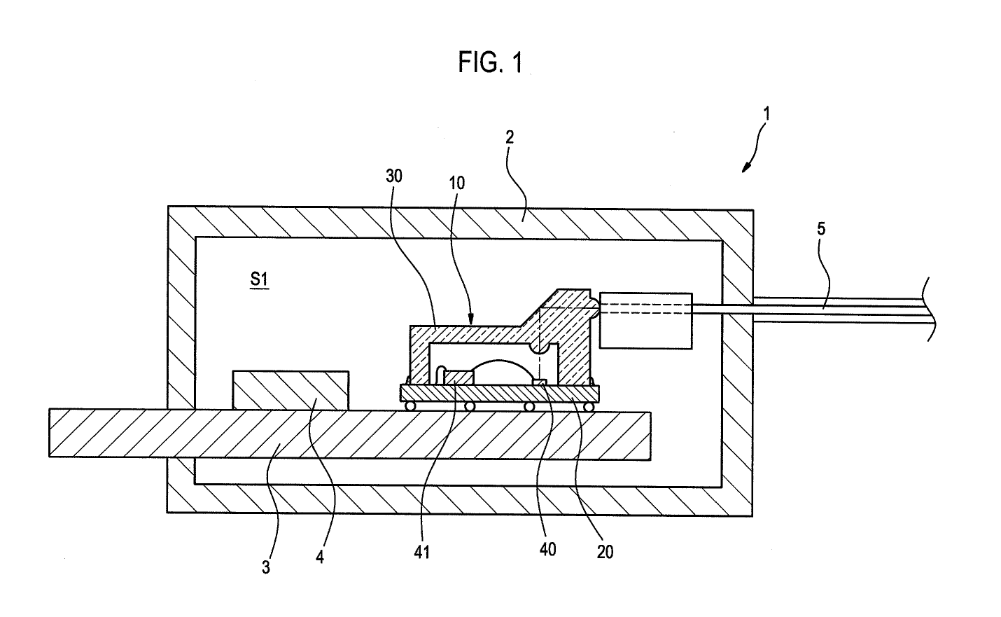

FIG. 1 is a cross sectional view of the optical module 1. The optical module 1 includes a box-shaped housing 2 of rectangular parallelepiped within which an internal space S1 is formed. Within the internal space S1, there are disposed a portion of a connector board 3, an optical connecting member 10 mounted on the connector board 3, a waveform shaper 4 electrically connected to the optical connecting member 10, and one end part of an optical fiber 5 optically coupled to the optical connecting member 10.

An electric signal inputted from one external equipment connected to the optical module 1 is inputted to the waveform shaper 4 through wirings provided on the connector board 3. The waveform shaper 4 serves to perform shaping of waveform of the electric signal to output such an electric signal to the optical connecting member 10. The optical connecting member 10 serves to convert such an electric signal into an optical signal to transmit such an optical signal to the other external equipment through the optical fiber 5. Conversely, the optical signal inputted from the optical fiber 5 from the other external equipment is converted into an electric signal by the optical connecting member 10, and the electric signal is subjected to waveform shaping by the waveform shaper 4, and is outputted to one external equipment through the wirings provided on the connector board 3.

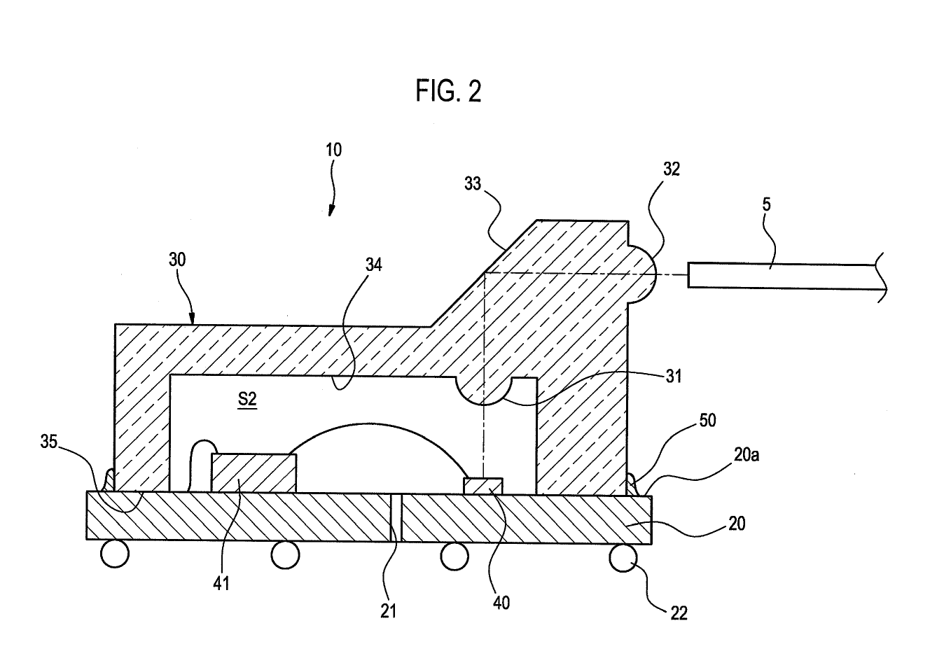

FIG. 2 is a cross sectional view of the optical connecting member 10 according to the first embodiment of the present invention.

The optical connecting member 10 includes a board chip 20, an optical element 40 mounted on the board chip 20, a circuit element 41 electrically connected to the optical element 40, and a lens member 30 optically connected to the optical element 40. The board chip 20 is mounted on the connector board 3 through solder balls 22 (See FIG. 1).

The optical element 40 is provided on an upper surface 20a of the printed circuit board 20. The optical element 40 includes a light emitting element represented as Vertical Cavity Surface Emitting LASER (VCSER), and a light receiving element represented as Photo Diode (PD). The optical element 40 is mounted on the upper face 20a of the board chip 20 in such a manner that its light emitting/light receiving surface is upwardly directed.

The circuit element 41 is constituted by a drive IC for inputting an electric signal to the light emitting element of the optical element 40, and a Transimpedance Amplifier (TIA) for amplifying such an electric signal from the light receiving element of the optical element 40.

A lens member 30 includes an element side lens part 31 directed toward the optical element 40, a fiber side lens part 32 directed toward the end face of the optical fiber 5, and a reflection surface 33 for optically connecting the element side lens part 31 and the fiber side lens part 32. Thus, the optical element 40 is optically connected to the optical fiber 5 through the lens member 30.

This lens member 30 is a resin molded product formed by transparent resin having a glass transition point higher than a melting temperature of solder. For example, the lens member 30 may be formed by ULTEM (Registered Trademark) and/or TERALINK (Registered Trademark).

This lens member 30 is configured so that a recessed part 34 is provided on the board chip 20 side, and an accommodating space S2 is formed between the recessed part 34 and the upper face 20a of the board chip 20. Within the accommodating space S2, there are accommodated the optical element 40 and the optical element 41. An adhesive agent 50 is coated over the entire circumference thereof at the outer circumference of a lower face 35 of the lens member 30 in contact with the upper face 20a of the board chip 20, and the lens member 30 is bonded to the upper face 20a of the board chip 20 without gap.

A very small through-hole (communicating part) 21 is provided at the board chip 20. Thus, the accommodating space S2 communicates with the outside of the accommodating space S2 only through the very small through-hole 21. Moreover, metallic plating may be implemented to an inner circumferential surface 21a of the through-hole 21. Further, a water-proof ventilation filter having a function to allow water not to pass, but to allow air to pass therethrough may be provided at the through-hole 21. It is preferable that a diameter of the through-hole 21 is 50 μm to 500 μm. In addition, a plurality of through-holes 21 may be provided.

In accordance with the optical connecting member 10 according to the first embodiment of the present invention as described above, the accommodating space S2 within which the optical element 40 is accommodated communicates with the outside of the accommodating space S2 through the through-hole 21 provided on the board chip 20. Thus, heat produced at the optical element 40 can be dissipated toward the outside via the through-hole 21. Accordingly, heat radiation performance of the optical element 40 can be enhanced. Particularly, since when the light emitting element of the optical element 40 is exposed to the environment of high temperature, the light emitting efficiency is lowered. For this reason, in accordance with the optical connecting member 10 according to this embodiment, the light emitting element of the optical element 40 can stably emits light at a high light emitting efficiency.

Moreover, since heat produced at the optical element 40 can be dissipated toward the outside, heat is difficult to stay within the lens member 30 so that thermal deformation of the lens member 30 can be suppressed. Accordingly, the relational position of the element side lens part 31 of the lens member 30, the reflecting surface 33 and the fiber side lens part 32 is difficult to change. For this reason, even if the optical connecting member 10 is used for a long time, the optical coupling between the optical element 40 and the optical fiber 5 can be maintained successfully.

Moreover, since heat can be dissipated through the through-hole 21 in this way, even if the lens member 30 is provided so as to cover the optical element 40, the temperature of the lens member 30 becomes difficult to rise in temperature depending upon heat produced at the optical element 40. For this reason, it is possible to suppress a temperature difference of the lens member 30 between temperature at the time of the operation of the optical connecting member 10 and that at the time of non-operation thereof. For this reason, it is possible to suppress expansion and contraction based on temperature change of the lens member 30. Accordingly, a heavy load is not exerted onto the adhesive agent 50 which fixes the lens member 30 on the board chip 20, thus making it possible to fix the lens member 30 on the board chip 20 stably for a long time.

Moreover, the lens member 30 is formed by transparent resin having a glass transition point higher than a melting temperature of solder. For this reason, even if the board chip 20 is mounted onto the connector board 3 together with electric components such as waveform shaper 4, etc. by solder reflow, there is no possibility that the lens member 30 may be deformed. Accordingly, since the mounting work can be collectively performed by solder reflow, it is possible to provide the optical connecting member 10 at a low cost.

Moreover, since the through-hole 21 is opened at the board chip 20 positioned on the side opposite to the light emitting/light receiving surface of the optical element 40, dust which may be entered through the through-hole 21 is difficult to be accumulated on the light emitting/light receiving surface. Particularly, it is preferable to provide a plurality of through-holes 21 having a diameter of 100 μm to 300 μm, so that heat produced at the optical element 40 can be dissipated toward the outside, and dust can be advantageously prevented from being entered.

Moreover, the thermal deformation of the board chip 20 formed by glass epoxy resin, etc. is smaller than the thermal deformation of the lens member 30. For this reason, it is possible to set the size of the through-hole 21 to a small value. Thus, the water-proof characteristic and the dust-proof characteristic can be improved. When a water-proof ventilation filter is attached to the through-hole 21, it is possible to further improve the water-proof characteristic or the dust-proof characteristic

Moreover, when metallic plating is implemented to the inner circumferential surface of the through-hole 21, it is possible to efficiently transmit heat within the accommodating space S2 toward the outside through the metallic plating with a high efficiency.

### Second Embodiment

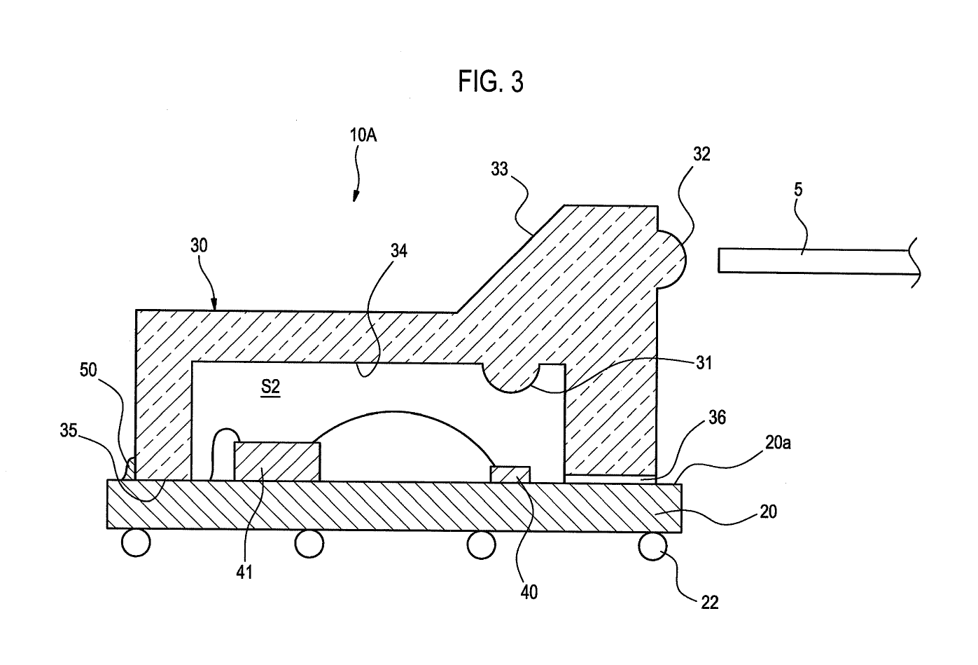

An optical connecting member 10A according to the second embodiment of the present invention will now be described with reference to FIG. 3. In this embodiment, the same reference numerals are respectively attached to portions common to those of the optical module 10 according to the previously described first embodiment, and their repetitive description will be omitted.

FIG. 3 is a cross sectional view of the optical connecting member 10A according to the second embodiment.

As shown in FIG. 3, the lens member 30 is fixed to the board chip 20 by the adhesive agent 50 except for a part thereof. Namely, a lower face 35 of the lens member 30 and an upper face 20a of the board chip 20 are bonded by means of the adhesive agent 50 so as to form a part where the adhesive agent 50 is partially not coated. At the part where the adhesive agent 50 is partially not coated, a gap (communicating part) 36 is formed between the lens member 30 and the board chip 20. It is preferable that the size of the gap 36 is 50 μm to 500 μm.

In accordance with the optical connecting member 10A according to this embodiment, it is possible to dissipate heat within the accommodating space S2 by the gap 36 toward the outside. Moreover, since there is no necessity to provide the through-hole at the board chip 20, processing of the board chip 20 becomes easy.

### Third Embodiment

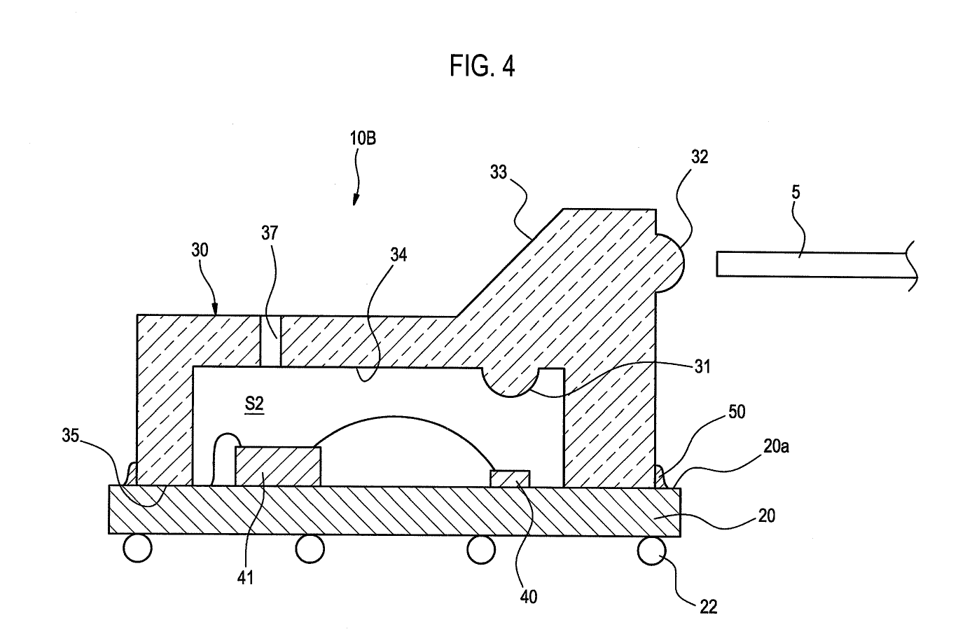

An optical connecting member 10B according to the third embodiment of the present invention will now be described with reference to FIG. 4. In this embodiment, the same reference numerals are respectively attached to parts common to those of the optical connecting members 10, 10A in the previously described embodiments, and their repetitive description will now be omitted.

FIG. 4 is a cross sectional view of the optical connecting member 10B according to the third embodiment.

As illustrated in FIG. 4, a through-hole 37 serving as a communicating part may be provided at the lens member 30. As illustrated in the figure, the through-hole 37 may be provided at the upper surface of the lens member 30, or may be provided at the side surface thereof. It is preferable that the diameter of the through-hole 37 is 50 μm to 500 μm. Further, a plurality of through-holes 37 may be provided. Since the optical module 10B according to this embodiment is configured so that the through-hole 37 is provided at the lens member 30, even in the case where there is no space required for providing the through-hole at the board chip 20, it is possible to dissipate heat within the accommodating space S2 toward the outside.

### Fourth Embodiment

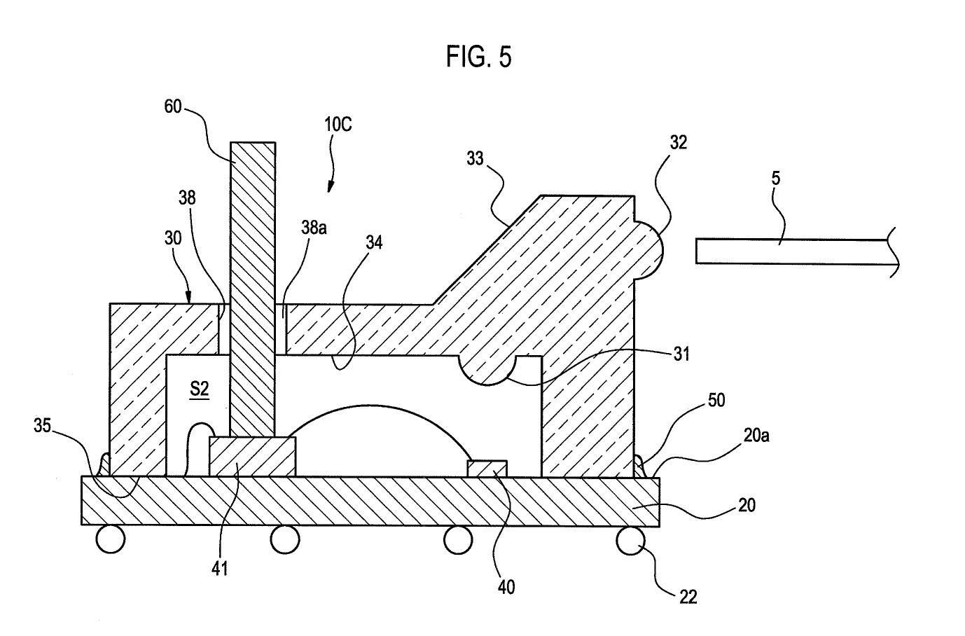

An optical connecting member 10C according to the fourth embodiment of the present invention will now be described with reference to FIG. 5. In this embodiment, the same reference numerals are respectively attached to portions common to the optical connecting members 10, 10A, 10B according to the previously described embodiments, and their repetitive description is omitted.

FIG. 5 is a cross sectional view of an optical connecting member 10C according to the fourth embodiment.

At the optical connecting member 10C according to this embodiment, an insertion hole 38 is provided at a portion facing to the circuit element 41 of the lens member 30. A heat radiating member 60 made of metal is inserted into the invention hole 38. One end of the heat radiating member 60 is thermally connected to the circuit element 41 within the accommodating space S2, and the other end is extended from one end side, and is penetrated via the insertion hole 38. Thus, such the other end is exposed to the outside of the accommodating space S2. In addition, a gap 38a as a communicating part is formed between the heat radiating member 60 and the insertion hole 38. It is preferable that the width of the gap 38a is 50 μm to 500 μm.

In accordance with the optical connecting member 10C according to this embodiment, it is possible to efficiently transmit, toward the outside, heat produced in the circuit element 41 through the heat radiating member 60 to radiate the heat thus transmitted. Moreover, it is possible to dissipate, toward the outside, heat within the accommodating space S2 through the gap 38a.

It is to be noted that although explanation has been given in the example illustrated by taking the example where the insertion hole 38 is provided at the portion facing to the circuit element 41 of the lens member 30 to thermally connect the circuit element 41 and the outside by the rod-shaped heat radiating member 60, the present invention is not limited to such an implementation. Such a insertion hole 38 may be provided at a position displaced from the circuit element 41 to thermally connect the circuit element 41 and the outside by means of a bent heat radiating member 60.

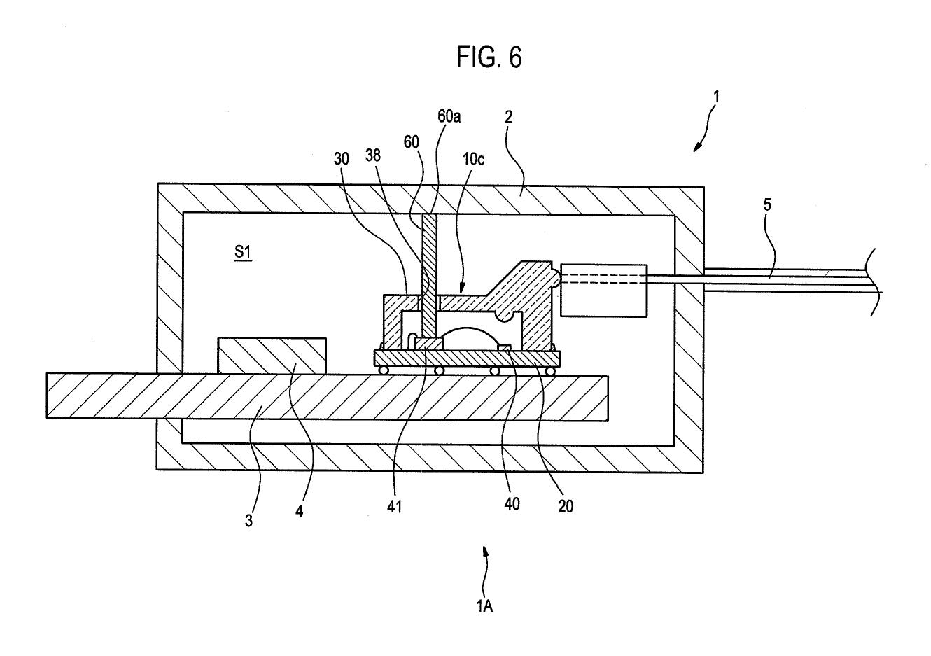

An example of the embodiment of an optical module according to the present invention will now be described with reference to FIG. 6. FIG. 6 is a cross sectional view of an optical module 1A according to this embodiment. The optical module 1A according to this embodiment is configured so that the optical connecting member 10C according to the previously described fourth embodiment is mounted on the connector board 3, wherein an upper end 60a of a heat radiating member 60 of the optical connecting member 10C is in contact with the housing 2.

In accordance with the optical module 1A according to this embodiment, heat produced at the circuit element 41 is transmitted to the housing 2 having a large thermal capacity through the heat radiating member 60. Accordingly, it is possible to more efficiently dissipate, toward the outside of the accommodating space S2, heat produced at the circuit element 41. Thus, the heat radiation performance of the optical connecting member 1A is further improved.

It should be noted that the optical connecting member of the present invention is not limited to the previously described respective embodiments, but modifications and/or improvements, etc. may be implemented as occasion demands.

While, e.g., explanation has been given in the above-described embodiments by taking the example where the optical connecting member is mounted in the optical module 1, the present invention is not limited to such an example. For example, in the case of optically connecting a personal computer and a monitor, an optical connecting member may be mounted at the optical module 1 connected to the personal computer as described above, or an optical connecting member may be mounted on a mother board of the personal computer.

Moreover, the lens member 30 in the previously described respective embodiments is only one example. For example, there may be employed, e.g., such a configuration that element side lens part 31 and fiber side lens part 32 are arranged in line, and optical element 40 and optical fiber 5 are linearly optically connected.

Moreover, while explanation has been given in the above-described embodiments by taking the example where the circuit element 41 is accommodated together with the optical element 40 within the accommodating space S2, there may be employed a configuration in which only optical element 40 may be accommodated within the accommodating space S2, or components except for the circuit element 41 are accommodated therewithin.

There may be employed a configuration in which the previously described respective embodiments may be combined to constitute an optical connecting member in which through-holes are provided both at the board chip 20 and the lens member 30.

In addition, while explanation has been given by taking the example in which the lens member 30 is directly mounted on the board chip 20 in the above-described embodiments, the present invention is not limited to such an example. For example, a frame shaped supporting member may be interposed between the lens member 30 and the board chip 20 so that an accommodating space S2 is formed therebetween to mount the lens member 30 at the board chip 20 through the supporting member. In this case, a through hole may be provided at the supporting member as communicating part, or gap between the supporting member and the lens member 30 or gap between the supporting member and the board chip 20 may be used as a communicating part.

What is claimed is:

1. An optical connecting member comprising:
a board chip;
an optical element mounted on the board chip; and
a lens member including a lens part optically connected to the optical element,
wherein an accommodating space for accommodating the optical element is formed between the lens member and the board chip, and
wherein the accommodating space communicates with the outside only through a very small communicating part.

2. The optical connecting member according to claim 1,
wherein the communicating part is a through-hole provided at the board chip.

3. The optical connecting member according to claim 2,
wherein metallic plating is implemented to an inner circumferential surface of the through-hole.

4. The optical connecting member according to claim 1,
wherein the lens member is fixed by an adhesive agent to the board chip except for a part of the lens member, and
wherein the communicating part is a gap between the part where the adhesive agent of the lens member is not coated and the board chip.

5. The optical connecting member according to claim 1,
wherein the communicating part is a through-hole provided at the lens member.

6. The optical connecting member according to claim 1, further comprising:
a drive circuit adapted to drive the optical element, mounted on the board chip and accommodated within the accommodating space; and
a heat radiating member having one end thermally connected to the drive circuit and the other end extended toward outside of the accommodating space,
wherein an insertion hole is provided at the lens member,
wherein the heat radiating member is extended toward outside of the accommodating space through the inserting hole, and
wherein the communicating part is a gap between the heat radiating member and the inserting hole.

7. The optical connecting member according to claim 1, further comprising:
a water-proof ventilation filter provided at the communicating part.

8. The optical connecting member according to claim 2,
wherein a diameter of the through-hole is 50 μm to 500 μm.

9. The optical connecting member according to claim 4,
wherein a size of the gap is 50 μm to 500 μm.

10. The optical connecting member according to claim 5,
wherein a diameter of the through-hole is 50 μm to 500 μm.

11. The optical connecting member according to claim 6,
wherein a width of the gap is 50 μm to 500 μm.

12. An optical module comprising:
the optical connecting member according to claim 6;
a mounting board on which the board chip is mounted; and
a housing adapted to accommodate the board chip and the mounting board,
wherein the heat radiating member is thermally connected to the housing.
